(19) United States
(12) Patent Application Publication
(10) Pub. No.: US 2023/0309211 A1
(43) Pub. Date: Sep. 28, 2023

(54) EXTREME ULTRAVIOLET LIGHT GENERATION APPARATUS AND ELECTRONIC DEVICE MANUFACTURING METHOD

(71) Applicant: Gigaphoton Inc., Tochigi (JP)

(72) Inventor: Yoshiyuki HONDA, Oyama-shi (JP)

(73) Assignee: Gigaphoton Inc., Tochigi (JP)

(21) Appl. No.: 18/163,529

(22) Filed: Feb. 2, 2023

(30) Foreign Application Priority Data
Mar. 25, 2022 (JP) 2022-049319

(51) Int. Cl. H05G 2/00; G03F 7/20

(52) U.S. Cl. CPC H05G 2/008; G03F 7/70033; H05G 2/005

(57) ABSTRACT

An extreme ultraviolet light generation apparatus includes a chamber including a plasma generation region; a target supply unit configured to supply a target to the plasma generation region; a laser light concentrating mirror configured to concentrate pulse laser light on the plasma generation region; and an EUV light concentrating mirror having a reflection surface reflecting extreme ultraviolet light radiated from the plasma generation region, and arranged such that the reflection surface falls within an angle range in which ion energy is less than an average value of the ion energy in a spatial distribution of the ion energy of ions diffused from the plasma generation region at positions of a predetermined distance from the plasma generation region.

The present application claims the benefit of Japanese Patent Application No. 2022-049319, filed on Mar. 25, 2022, the entire contents of which are hereby incorporated by reference.

### BACKGROUND

### 1. Technical Field

The present disclosure relates to an extreme ultraviolet light generation apparatus, and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, the development of an exposure apparatus that combines an extreme ultraviolet (EUV) light generation apparatus that generates EUV light having a wavelength of about 13 nm and reduced projection reflection optics is expected.

As the EUV light generation apparatus, a laser produced plasma (LPP) type apparatus using plasma generated by irradiating a target substance with pulse laser light has been developed.

### PATENT DOCUMENTS

### List of Documents

Patent Document 1: US Patent Application Publication No. 2010/078579

### SUMMARY

An extreme ultraviolet light generation apparatus according to an aspect of the present disclosure includes a chamber including a plasma generation region; a target supply unit configured to supply a target to the plasma generation region; a laser light concentrating mirror configured to concentrate pulse laser light on the plasma generation region; and an EUV light concentrating mirror having a reflection surface reflecting EUV light radiated from the plasma generation region, and arranged such that the reflection surface falls within an angle range in which ion energy is less than an average value of the ion energy in a spatial distribution of the ion energy of ions diffused from the plasma generation region at positions of a predetermined distance from the plasma generation region.

An electronic device manufacturing method according to an aspect of the present disclosure includes generating extreme ultraviolet light using an extreme ultraviolet light generation apparatus, outputting the extreme ultraviolet light to an exposure apparatus, and exposing a photosensitive substrate to the extreme ultraviolet light in the exposure apparatus to manufacture an electronic device. Here, the extreme ultraviolet light generation apparatus includes a chamber including a plasma generation region; a target supply unit configured to supply a target to the plasma generation region; a laser light concentrating mirror configured to concentrate pulse laser light on the plasma generation region; and an EUV light concentrating mirror having a reflection surface reflecting the extreme ultraviolet light radiated from the plasma generation region, and arranged such that the reflection surface falls within an angle range in which ion energy is less than an average value of the ion energy in a spatial distribution of the ion energy of ions diffused from the plasma generation region at positions of a predetermined distance from the plasma generation region.

An electronic device manufacturing method according to an aspect of the present disclosure includes inspecting a defect of a mask by irradiating the mask with extreme ultraviolet light generated by an extreme ultraviolet light generation apparatus, selecting a mask using a result of the inspection, and exposing and transferring a pattern formed on the selected mask onto a photosensitive substrate, the extreme ultraviolet light generation apparatus including a chamber including a plasma generation region; a target supply unit configured to supply a target to the plasma generation region; a laser light concentrating mirror configured to concentrate pulse laser light on the plasma generation region; and an EUV light concentrating mirror having a reflection surface reflecting the extreme ultraviolet light radiated from the plasma generation region, and arranged such that the reflection surface falls within an angle range in which ion energy is less than an average value of the ion energy in a spatial distribution of the ion energy of ions diffused from the plasma generation region at positions of a predetermined distance from the plasma generation region.

### BRIEF DESCRIPTION OF THE DRAWINGS

Embodiments of the present disclosure will be described below merely as examples with reference to the accompanying drawings.

FIG. 1 schematically shows the configuration of an EUV light generation system according to a comparative example.

FIG. 2 shows the arrangement of an EUV light concentrating mirror in the comparative example.

FIG. 3 shows the arrangement of the EUV light concentrating mirror in a first embodiment.

FIG. 4 is a graph showing a spatial distribution of the ion energy when the pulse width of pulse laser light is 4 ns.

FIG. 5 shows a state in which a target is irradiated with prepulse laser light.

FIG. 6 shows a state in which a secondary target is irradiated with the pulse laser light.

FIG. 7 shows a state in which ions of a target substance diffuse from the secondary target irradiated with the pulse laser light.

FIG. 8 shows the arrangement of the EUV light concentrating mirror in a second embodiment.

FIG. 9 shows the arrangement of the EUV light concentrating mirror in a third embodiment.

FIG. 10 is a graph showing a spatial distribution of ion energy when the pulse width of the pulse laser light is 20 ns.

FIG. 11 shows a state in which the target is irradiated with the prepulse laser light.

FIG. 12 shows a state in which the secondary target is irradiated with the pulse laser light in time series along with FIGS. 13 and 14.

FIG. 13 shows a state in which the secondary target is irradiated with the pulse laser light in time series along with FIGS. 12 and 14.

FIG. 14 shows a state in which the secondary target is irradiated with the pulse laser light in time series along with FIGS. 12 and 13.

FIG. 15 shows the arrangement of the EUV light concentrating mirror in a fourth embodiment.

FIG. 16 shows a first example of an ion detector arranged to detect the ion energy.

FIG. 17 shows a second example of the ion detector arranged to detect the ion energy.

FIG. 18 shows an example of a detection result by the ion detector.

FIG. 19 schematically shows the configuration of an exposure apparatus connected to the EUV light generation system.

FIG. 20 schematically shows the configuration of an inspection apparatus connected to the EUV light generation system.

### DESCRIPTION OF EMBODIMENTS

### <Contents>

1. Comparative example
   1.1 Configuration
   1.2 Operation
2. Problem of comparative example
3. EUV light concentrating mirror 23 arranged in angle range of 90° to 180°
   3.1 Arrangement of EUV light concentrating mirror 23
   3.2 Spatial distribution of ion energy
   3.3 Factor of occurrence of spatial distribution of ion energy
   3.4 Effect
4. EUV light concentrating mirror 23 arranged in angle range of 125° to 180°
   4.1 Arrangement of EUV light concentrating mirror 23
   4.2 Spatial distribution of ion energy
   4.3 Effect
5. EUV light concentrating mirror 23 arranged in angle range of 21° to 127°
   5.1 Arrangement of EUV light concentrating mirror 23
   5.2 Spatial distribution of ion energy
   5.3 Factor of occurrence of spatial distribution of ion energy
   5.4 Effect
6. EUV light concentrating mirror 23 having through hole 24 surrounding angle range of 21°
   6.1 Arrangement of EUV light concentrating mirror 23
   6.2 Effect
7. Others
   7.1 Measurement of ion energy
      7.1.1 Arrangement of ion detector
      7.1.2 Calculation method of ion energy
      7.1.3 Effect
   7.2 Example of EUV light utilization apparatus 6
   7.3 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. Comparative Example

### 1.1 Configuration

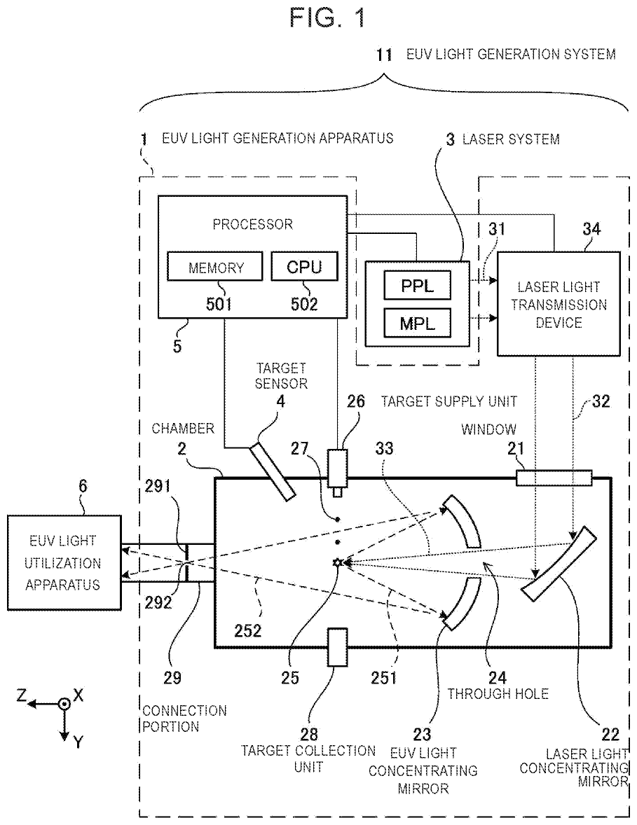

FIG. 1 schematically shows the configuration of an EUV light generation system 11 according to a comparative example. An EUV light generation apparatus 1 is used together with a laser system 3. In the present disclosure, a system including the EUV light generation apparatus 1 and the laser system 3 is referred to as the EUV light generation system 11.

The laser system 3 includes a prepulse laser device PPL (not shown) that outputs prepulse laser light in addition to a main pulse laser device MPL that outputs pulse laser light 31. The pulse laser light 31 is also referred to as main pulse laser light.

The EUV light generation apparatus 1 includes a chamber 2 and a target supply unit 26. The chamber 2 is a sealable container. The target supply unit 26 supplies a target 27 containing a target substance into the chamber 2. The material of the target substance may include tin, terbium, gadolinium, lithium, xenon, or a combination of any two or more thereof.

A through hole is formed in a wall of the chamber 2. The through hole is blocked by a window 21 and pulse laser light 32 output from the laser system 3 passes through the window 21. An EUV light concentrating mirror 23 having a spheroidal reflection surface is arranged in the chamber 2. The EUV light concentrating mirror 23 has first and second focal points. A multilayer reflection film in which molybdenum and silicon are alternately stacked is formed on a surface of the EUV light concentrating mirror 23. The EUV light concentrating mirror 23 is arranged such that the first focal point is located in a plasma generation region 25 and the second focal point is located at an intermediate focal point 292. A through hole 24 is formed at the center of the EUV light concentrating mirror 23, and pulse laser light 33 passes through the through hole 24.

The direction directing from the first focal point to the second focal point is represented by the Z direction. The travel direction of the target 27 perpendicular to the Z direction is represented by the Y direction. The direction perpendicular to both the Y direction and the Z direction is represented by the X direction.

The EUV light generation apparatus 1 includes a processor 5, a target sensor 4, and the like. The processor 5 is a processing device including a memory 501 in which a control program is stored, and a central processing unit (CPU) 502 which executes the control program. The processor 5 is specifically configured or programmed to perform various processes included in the present disclosure. The target sensor 4 detects at least one of the presence, trajectory, position, and velocity of the target 27. The target sensor 4 may have an imaging function.

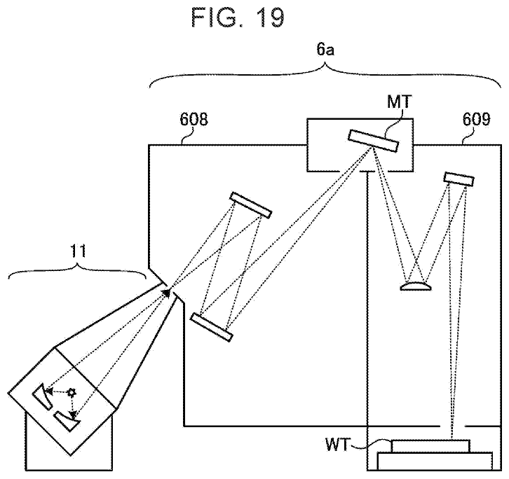

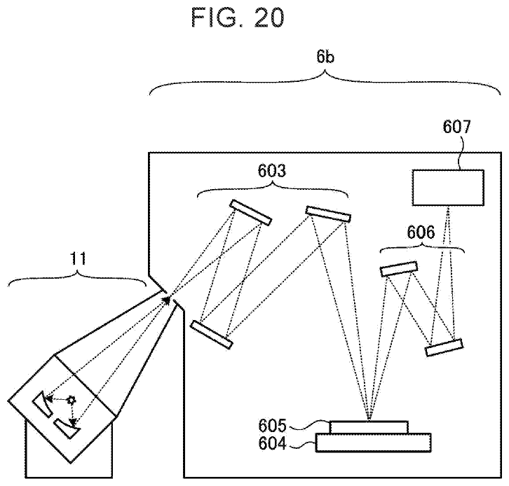

Further, the EUV light generation apparatus 1 includes a connection portion 29 providing communication between the internal space of the chamber 2 and the internal space of an EUV light utilization apparatus 6. An example of the EUV light utilization apparatus 6 will be described later with reference to FIGS. 19 and 20. A wall 291 in which an aperture is formed is arranged in the connection portion 29. The wall 291 is arranged such that the aperture is located at the second focal point of the EUV light concentrating mirror 23.

Further, the EUV light generation apparatus 1 includes a laser light transmission device 34, a laser light concentrating mirror 22, a target collection unit 28 for collecting the target 27, and the like. The laser light transmission device 34 includes an optical element for defining a transmission state of laser light, and an actuator for adjusting the position, posture, and the like of the optical element.

### 1.2 Operation

Operation of the EUV light generation system 11 will be described with reference to FIG. 1. The pulse laser light 31 output from the laser system 3 enters, via the laser light transmission device 34, the chamber 2 through the window 21 as the pulse laser light 32. The pulse laser light 32 travels along a laser light path in the chamber 2, is reflected by the laser light concentrating mirror 22, and is radiated to the target 27 as the pulse laser light 33. The prepulse laser light shares an optical path with the pulse laser light 32 by the laser light transmission device 34, is reflected by the laser light concentrating mirror 22, and is radiated to the target 27 before the pulse laser light 33. Alternatively, the prepulse laser light may pass through an optical path different from that of the pulse laser light 33 and be radiated to the target 27.

The wavelengths of the pulse laser light 33 and the prepulse laser light are suitably 1.06 μm of an yttrium aluminum garnet (YAG) laser, but may be 355 nm of the third harmonic of a YAG laser, 532 nm of the second harmonic of the YAG laser, 1.3 μm of an yttrium lithium fluoride (YLF) laser, or 10.6 μm by a CO₂ laser.

The fluence of the prepulse laser light is equal to or more than 0.1 J/cm² and equal to or less than 100 J/cm² at the irradiation position of the target 27, and the pulse width thereof is 1 ps or more and 100 ns or less. The fluence of the pulse laser light 33 is equal to or more than 10 J/cm² and equal to or less than 3000 J/cm² at the irradiation position of the target 27, and the pulse width thereof is equal to or more than 1 ns and equal to or less than 100 ns.

It is more preferable that the fluence of the prepulse laser light is equal to or more than 1 J/cm² and equal to or less than 20 J/cm². It is more preferable that the fluence of the pulse laser light 33 is equal to or more than 100 J/cm² and equal to or less than 2000 J/cm². It is more preferable that the pulse width of the pulse laser light 33 is equal to or more than 4 ns and equal to or less than 20 ns.

The target supply unit 26 outputs the target 27 toward the plasma generation region 25 in the chamber 2. The target 27 is irradiated with the pulse laser light 33. The target 27 irradiated with the pulse laser light 33 is turned into plasma, and radiation light 251 is radiated from the plasma. The EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6. Here, one target 27 may be irradiated with a plurality of pulses included in the pulse laser light 33.

The processor 5 controls the entire EUV light generation system 11. The processor 5 processes a detection result of the target sensor 4. Based on the detection result of the target sensor 4, the processor 5 controls the timing at which the target 27 is output, the output direction of the target 27, and the like. Further, the processor 5 controls oscillation timing of the laser system 3, a travel direction of the pulse laser light 32, the concentration position of the pulse laser light 33, and the like. The above-described various kinds of control are merely examples, and other control may be added as necessary.

### 2. Problem of Comparative Example

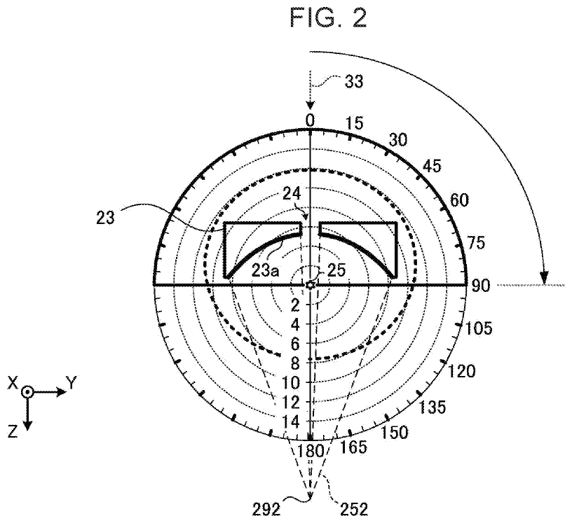

FIG. 2 shows the arrangement of the EUV light concentrating mirror 23 in the comparative example. The direction opposite to the travel direction of the pulse laser light 33 toward the plasma generation region 25 is defined as 0°. Angles with respect to the direction of 0° are indicated by numerical values of 15, 30, 45, . . . , 180.

The EUV light concentrating mirror 23 is arranged such that the through hole 24 thereof is positioned in the direction of 0°. The first focal point of the reflection surface 23a is located in the plasma generation region 25, and the intermediate focal point 292 of the reflection light 252, which is the second focal point, is located in the direction of 180°.

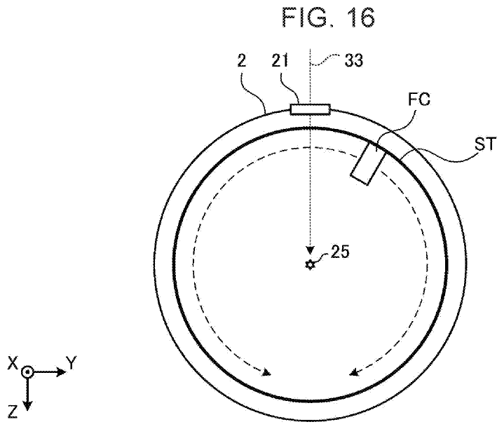

FIG. 2 further shows a polar coordinate graph for a spatial distribution of ion energy in the comparative example. With the plasma generation region 25 as the origin, the distance from the origin to the thick broken line in each direction corresponds to the magnitude of the ion energy of the target substance at a position of a predetermined distance from the plasma generation region 25. The magnitude of the ion energy is indicated by numerical values of 2, 4, 6, . . . , 14 given to concentric circles of thin broken lines centered on the plasma generation region 25, and the unit is keV. A measuring method of the ion energy will be described later with reference to FIGS. 16 to 18.

The spatial distribution of the ion energy is substantially axially symmetric with respect to the optical path axis of the pulse laser light 33. In the spatial distribution, the ion energy is higher in the angle range of 0° to 90° than in the angle range of 90° to 180°. In the comparative example, the reflection surface 23a of the EUV light concentrating mirror 23 is located in the angle range of 0° to 90° where the ion energy is high. There is a possibility that the EUV light concentrating mirror 23 may be contaminated by ions of the target substance having high ion energy, may be deteriorated, or may have a short lifetime.

### 3. EUV Light Concentrating Mirror 23 Arranged in Angle Range of 90° to 180°

### 3.1 Arrangement of EUV Light Concentrating Mirror 23

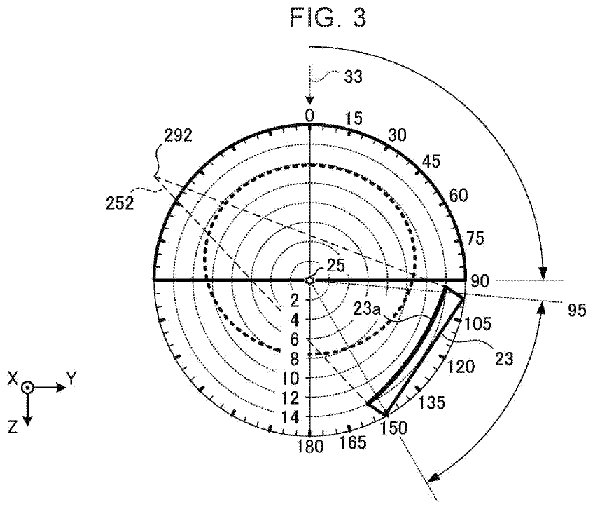

FIG. 3 shows the arrangement of the EUV light concentrating mirror 23 in a first embodiment. In FIG. 2, the pulse laser light 33 passes through the through hole 24 of the EUV light concentrating mirror 23 and is concentrated on the plasma generation region 25, whereas in FIG. 3, the pulse laser light 33 passes outside the EUV light concentrating mirror 23 and is concentrated on the plasma generation region 25. The outer edge of the reflection surface 23a viewed from the intermediate focal point 292 is substantially circular. The spatial distribution of the ion energy is similar to that shown in FIG. 2.

The EUV light concentrating mirror 23 is arranged such that the entire reflection surface 23a falls within an angle range in which the angle with respect to the direction opposite to the travel direction of the pulse laser light 33 entering the plasma generation region 25 is more than 90° and equal to or less than 180°. That is, it is desirable that all or a part of the reflection surface 23a is not arranged in the angle range of being equal to or more than 0° and equal to or less than 90°.

Further, it is preferable that the EUV light concentrating mirror 23 is not arranged at the position of 180° through which the pulse laser light 33 having passed through the plasma generation region 25 passes. The pulse laser light 33 having passed through the plasma generation region 25 passes outside the EUV light concentrating mirror 23 and enters a laser damper (not shown).

However, when the angle range in which the reflection surface 23a is located is too narrow, the amount of the EUV light reaching the intermediate focal point 292 may be insufficient. It is preferable that the EUV light concentrating mirror 23 is arranged such that the reflection surface 23a extends from a position where the angle is 95° to a position where the angle is 150°. The EUV light concentrating mirror 23 may extend outside the angle range of being equal to or more than 95° and equal to or less than 150° as long as being within the angle range of being more than 90° and equal to or less than 180°.

### 3.2 Spatial Distribution of Ion Energy

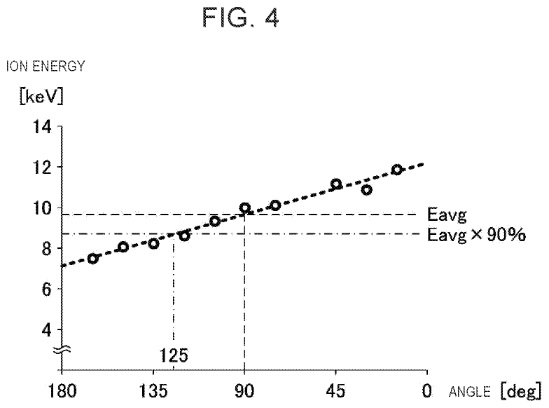

FIG. 4 is a graph showing a spatial distribution of the ion energy when the pulse width of the pulse laser light 33 is 4 ns. Open circles in FIG. 4 indicate measurement results in several directions, and a thick dashed line indicates an approximate straight line derived from the measurement results. The spatial distributions of the ion energy shown in FIGS. 2 and 3 correspond to the polar coordinate graph of FIG. 4.

In FIG. 4, the average value of the ion energy of the target substance measured at each of a plurality of angles between 0° and 180° is represented by Eavg. The target substance is, for example, tin. In the angle range of being more than 90° and equal to or less than 180°, the ion energy is less than the average value Eavg. By arranging the EUV light concentrating mirror 23 such that the reflection surface 23a falls within an angle range in which the ion energy is less than the average value Eavg, contamination of the reflection surface 23a due to ions of the target substance can be suppressed. The pulse width of the pulse laser light 33 is not limited to 4 ns, and similar results can be obtained as long as the pulse width is within a range of being equal to or more than 3.6 ns and equal to or less than 4.4 ns.

### 3.3 Factor of Occurrence of Spatial Distribution of Ion Energy

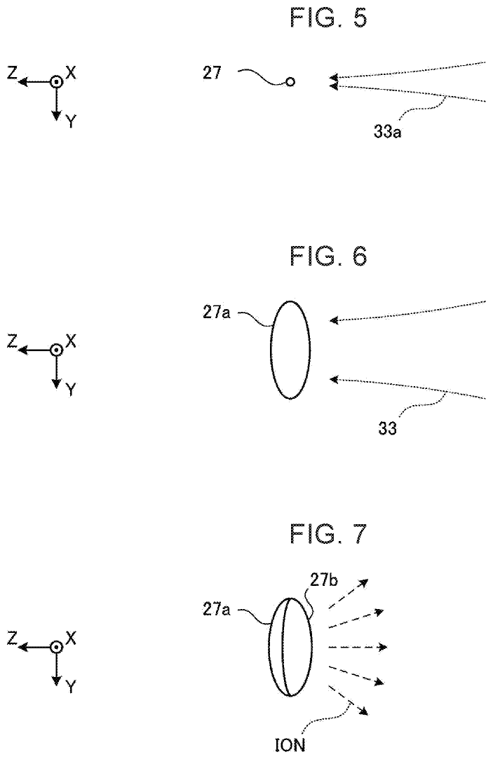

FIG. 5 shows a state in which the target 27 is irradiated with the prepulse laser light 33a. The target 27 is diffused or expanded by the energy of the prepulse laser light 33a and becomes a secondary target 27a shown in FIG.

FIG. 6 shows a state in which the secondary target 27a is irradiated with the pulse laser light 33. The pulse width of the pulse laser light 33 is 4 ns.

FIG. 7 shows a state in which ions ION of the target substance diffuse from the secondary target 27a irradiated with the pulse laser light 33. Since the pulse laser light 33 in the first embodiment has a pulse width as short as 4 ns and has high light intensity, a part of the secondary target 27a is rapidly heated. As a result, a low-density region 27b including high-energy particles is generated in a part of the secondary target 27a. The ions ION of the target substance are radiated from the region 27b. When the low-density region 27b is biased toward the upstream side of the pulse laser light 33, that is, toward the −Z side in FIG. 7, the ions ION are radiated more in the −Z direction. It is presumed that the spatial distribution of the ion energy shown in FIGS. 2 to 4 is caused as described above.

### 3.4 Effect

(1) According to the first embodiment, the EUV light generation apparatus 1 includes the chamber 2 including the plasma generation region 25, the target supply unit 26, the laser light concentrating mirror 22, and the EUV light concentrating mirror 23. The target supply unit 26 supplies the target 27 to the plasma generation region 25. The laser light concentrating mirror 22 concentrates the pulse laser light 33 on the plasma generation region 25. The EUV light concentrating mirror 23 has the reflection surface 23a that reflects the EUV light radiated from the plasma generation region 25, and is arranged such that the reflection surface 23a falls within the angle range in which the ion energy is less than the average value Eavg of the ion energy in the spatial distribution of the ion energy of the ions diffused from the plasma generation region 25 at positions of a predetermined distance from the plasma generation region 25.

According to this, since the reflection surface 23a is within the region where the ion energy is low, contamination of the reflection surface 23a can be suppressed.

(2) According to the first embodiment, the EUV light generation apparatus 1 further includes the prepulse laser device PPL that outputs the prepulse laser light with which the target 27 is irradiated, and the main pulse laser device MPL that outputs the pulse laser light 33 with which the target 27 irradiated with the prepulse laser light is irradiated. The laser light concentrating mirror 22 concentrates both the prepulse laser light and the pulse laser light 33 on the plasma generation region 25.

According to this, since the prepulse laser light and the pulse laser light 33 are radiated to the target 27 from the same direction, the rotational symmetry axis of the shape of the secondary target 27a and the optical path axis of the pulse laser light 33 coincide with each other, and the diffusion direction of the ions can be stabilized. In addition, by making the optical path axis of the prepulse laser light and the optical path axis of the pulse laser light 33 coincide with each other and commonly using the optical system including the laser light concentrating mirror 22 for irradiating the target 27 with the prepulse laser light and the pulse laser light 33, the pointing accuracy of these light can be improved and the diffusion direction of the ions can be stabilized.

(3) According to the first embodiment, the fluence of the prepulse laser light is equal to or more than 0.1 J/cm² and equal to or less than 100 J/cm², and the pulse width thereof is equal to or more than 1 ps and equal to or less than 100 ns. The fluence of the pulse laser light 33 is equal to or more than 10 J/cm² and equal to or less than 3000 J/cm², and the pulse width thereof is equal to or more than 1 ns and equal to or less than 100 ns.

According to this, EUV light can be efficiently generated by radiating the pulse laser light 33 to the secondary target 27a having a preferable density through diffusion and expansion of the target 27 with the prepulse laser light.

(4) The fluence of the prepulse laser light is more preferably equal to or more than 1 J/cm² and equal to or less than 20 J/cm², and the pulse width thereof is more preferably equal to or more than 1 ps and equal to or less than 100 ns. The fluence of the pulse laser light 33 is more preferably equal to or more than 100 J/cm² and equal to or less than 2000 J/cm², and the pulse width thereof is more preferably equal to or more than 4 ns and equal to or less than 20 ns.

According to this, the EUV light can be generated more efficiently.

(5) In the first embodiment, the average value Eavg is an average of the ion energy measured at each of the plurality of angles between 0° and 180° with respect to the direction opposite to the travel direction of the pulse laser light 33 entering the plasma generation region 25.

According to this, the design of the EUV light generation apparatus 1 can be simplified by assuming that the spatial distribution of the ion energy is axially symmetric about the optical path axis of the pulse laser light 33.

(6) According to the first embodiment, the laser light concentrating mirror 22 is arranged such that the pulse laser light 33 passes outside the EUV light concentrating mirror 23 and is concentrated on the plasma generation region 25.

According to this, since the through hole 24 through which the pulse laser light 33 passes is not required to be formed at the EUV light concentrating mirror 23, the concentration efficiency can be improved, and the EUV light concentrating mirror 23 can be reduced in size.

(7) According to the first embodiment, the target 27 includes tin, and the pulse width of the pulse laser light 33 is in the range of being equal to or more than 3.6 ns and equal to or less than 4.4 ns. The angle range within which the reflection surface 23a should fall is a range of the angle being more than 90° and equal to or less than 180° with respect to the direction opposite to the travel direction of the pulse laser light 33 entering the plasma generation region 25.

According to this, the reflection surface 23a can fall within the region where the ion energy is low, and contamination of the reflection surface 23a can be suppressed.

(8) According to the first embodiment, the EUV light concentrating mirror 23 is arranged such that the reflection surface 23a extends from a position at which the angle with respect to the direction opposite to the travel direction of the pulse laser light 33 entering the plasma generation region 25 is 95° to a position at which the angle is 150°.

According to this, a high EUV light concentration efficiency can be obtained by widely using an angle range in which the ion energy is low.

In other respects, the first embodiment is similar to the comparative example.

### 4. EUV Light Concentrating Mirror 23 Arranged in Angle Range of 125° to 180°

### 4.1 Arrangement of EUV Light Concentrating Mirror 23

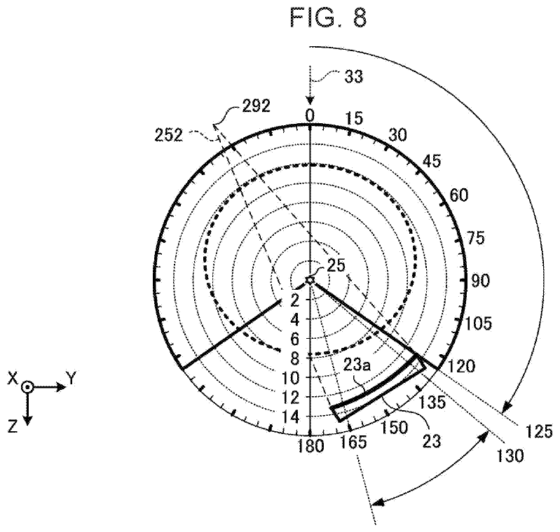

FIG. 8 shows the arrangement of the EUV light concentrating mirror 23 in a second embodiment. The outer edge of the reflection surface 23a viewed from the intermediate focal point 292 is substantially circular. The spatial distribution of the ion energy is similar to that shown in FIG. 2 and FIG. 3.

The EUV light concentrating mirror 23 is arranged such that the entire reflection surface 23a falls within an angle range in which the angle with respect to the direction opposite to the travel direction of the pulse laser light 33 entering the plasma generation region 25 is more than 125° and equal to or less than 180°. That is, it is desirable that all or a part of the reflection surface 23a is not arranged in the angle range of being equal to or more than 0° and equal to or less than 125°.

However, when the angle range in which the reflection surface 23a is located is too narrow, the amount of the EUV light reaching the intermediate focal point 292 may be insufficient. It is preferable that the EUV light concentrating mirror 23 is arranged such that the reflection surface 23a extends from a position where the angle is 130° to a position where the angle is 165°. The EUV light concentrating mirror 23 may extend outside the angle range of being equal to or more than 130° and equal to or less than 165° as long as being within the angle range of being more than 125° and equal to or less than 180°.

### 4.2 Spatial Distribution of Ion Energy

Referring again to FIG. 4, in the angle range of being more than 125° and equal to or less than 180°, the ion energy is less than 90% of the average value Eavg. By arranging the EUV light concentrating mirror 23 such that the reflection surface 23a falls within an angle range in which the ion energy is less than 90% of the average value Eavg, contamination of the reflection surface 23a due to ions of the target substance can be further suppressed.

### 4.3 Effect

(9) According to the second embodiment, the EUV light concentrating mirror 23 is arranged such that the reflection surface 23a falls within an angle range in which the ion energy is less than 90% of the average value Eavg.

According to this, by arranging the EUV light concentrating mirror 23 only in the angle range in which the ion energy is lower than that in the angle range in the first embodiment, the contamination of the reflection surface 23a can be further suppressed.

(10) According to the second embodiment, the target 27 includes tin, and the pulse width of the pulse laser light 33 is in the range of being equal to or more than 3.6 ns and equal to or less than 4.4 ns. The angle range within which the reflection surface 23a should fall is a range of the angle being more than 125° and equal to or less than 180° with respect to the direction opposite to the travel direction of the pulse laser light 33 entering the plasma generation region 25.

According to this, the reflection surface 23a can fall within the region where the ion energy is low, and contamination of the reflection surface 23a can be suppressed.

(11) According to the second embodiment, the EUV light concentrating mirror 23 is arranged such that the reflection surface 23a extends from a position at which the angle with respect to the direction opposite to the travel direction of the pulse laser light 33 entering the plasma generation region 25 is 130° to a position at which the angle is 165°.

According to this, a high EUV light concentration efficiency can be obtained by widely using an angle range in which ion energy is low.

In other respects, the second embodiment is similar to the first embodiment.

### 5. EUV Light Concentrating Mirror 23 Arranged in Angle Range of 21° to 127°

### 5.1 Arrangement of EUV Light Concentrating Mirror 23

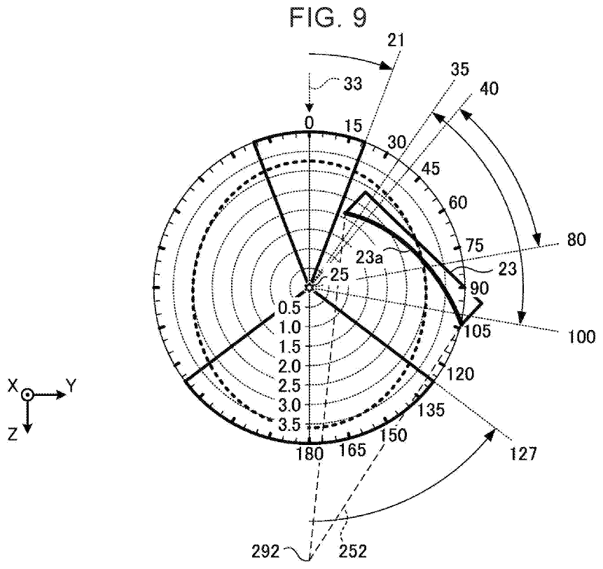

FIG. 9 shows the arrangement of the EUV light concentrating mirror 23 in a third embodiment. In the third embodiment, the EUV light concentrating mirror 23 is inclined so that the reflection light 252 reflected by the EUV light concentrating mirror 23 does not pass through the plasma generation region 25. The outer edge of the reflection surface 23a viewed from the intermediate focal point 292 is substantially circular.

FIG. 9 further shows a polar coordinate graph of the spatial distribution of the ion energy in the third embodiment. In the spatial distribution, the ion energy is higher in the angle range from 0° to 21° and in the angle range of 127° to 180° than in the angle range of 21° to 127°.

The EUV light concentrating mirror 23 is arranged such that the entire reflection surface 23a falls within an angle range in which the angle with respect to the direction opposite to the travel direction of the pulse laser light 33 entering the plasma generation region 25 is more than 21° and less than 127°. That is, it is desirable that all or a part of the reflection surface 23a is not arranged in the angle range of being equal to or more than 0° and equal to or less than 21° and in the angle range of being equal to or more than 127° and equal to or less than 180°.

However, when the angle range in which the reflection surface 23a is located is too narrow, the amount of the EUV light reaching the intermediate focal point 292 may be insufficient. The EUV light concentrating mirror 23 is preferably arranged such that the reflection surface 23a extends from a position where the angle is 40° to a position where the angle is 80°, and more preferably arranged such that the reflection surface 23a extends from a position where the angle is 35° to a position where the angle is 100°. The EUV light concentrating mirror 23 may extend outside the angle range of being equal to or more than 35° and equal to or less than 100° as long as it falls within the angle range of being more than 21° and less than 127°.

### 5.2 Spatial Distribution of Ion Energy

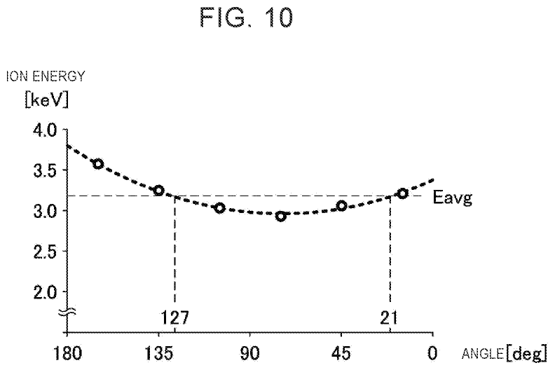

FIG. 10 is a graph showing a spatial distribution of the ion energy when the pulse width of the pulse laser light 33 is 20 ns. Open circles in FIG. 10 indicate measurement results in several directions, and a thick dashed line indicates an approximation curve line derived from the measurement results. The spatial distribution of the ion energy shown in FIG. 9 corresponds to the polar coordinate graph of FIG. 10.

In FIG. 10, the average value of the ion energy of the target substance measured at each of a plurality of angles between 0° and 180° is represented by Eavg. The target substance is, for example, tin. In the angle range of being more than 21° and equal to or less than 127°, the ion energy is less than the average value Eavg. By arranging the EUV light concentrating mirror 23 such that the reflection surface 23a falls within an angle range in which the ion energy is less than the average value Eavg, contamination of the reflection surface 23a due to ions of the target substance can be suppressed. The pulse width of the pulse laser light 33 is not limited to 20 ns, and similar results can be obtained as long as the pulse width is within a range of being equal to or more than 18 ns and equal to or less than 22 ns.

### 5.3 Factor of Occurrence of Spatial Distribution of Ion Energy

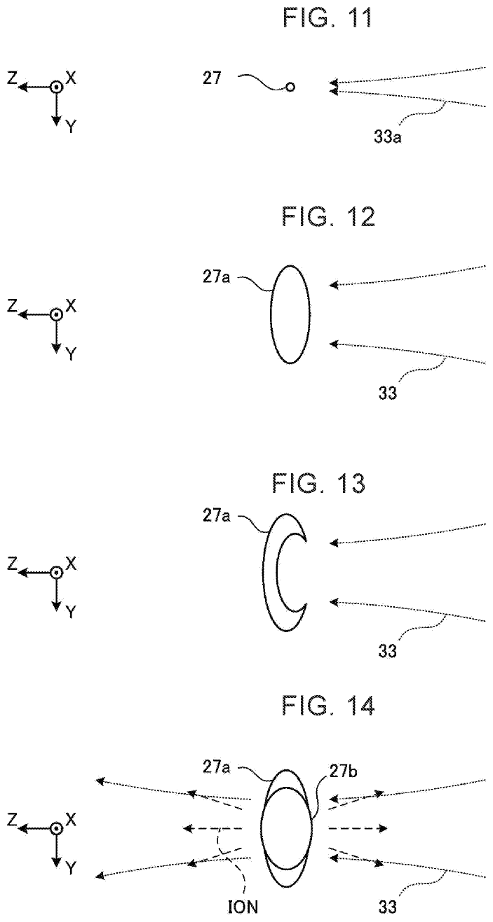

FIG. 11 shows a state in which the target 27 is irradiated with the prepulse laser light 33a. FIG. 11 is similar to FIG. 5.

FIGS. 12 to 14 show states, in time series, in which the secondary target 27a is irradiated with the pulse laser light 33. The pulse width of the pulse laser light 33 is 20 ns. Since the pulse laser light 33 in the third embodiment has a pulse width as long as 20 ns and has light intensity lower than that in the case of the pulse width being as short as 4 ns with the same fluence, the secondary target 27a is gently heated. As a result, as shown in FIG. 14, the low-density region 27b including high-energy particles is generated to penetrate the secondary target 27a. The ions ION of the target substance are radiated from the region 27b. When the low-density region 27b penetrates from the upstream side to the downstream side of the pulse laser light 33, the ions ION are radiated in both the +Z direction and the −Z direction. It is presumed that the spatial distribution of the ion energy shown in FIGS. 9 and 10 is caused as described above.

### 5.4 Effect

(12) According to the third embodiment, the target 27 includes tin, and the pulse width of the pulse laser light 33 is in the range of being equal to or more than 18 ns and equal to or less than 22 ns. The angle range within which the reflection surface 23a should fall is a range of the angle being more than 21° and less than 127° with respect to the direction opposite to the travel direction of the pulse laser light 33 entering the plasma generation region 25.

According to this, the reflection surface 23a can fall within the region where the ion energy is low, and contamination of the reflection surface 23a can be suppressed.

(13) According to the third embodiment, the EUV light concentrating mirror 23 is arranged such that the reflection surface 23a extends from a position at which the angle with respect to the direction opposite to the travel direction of the pulse laser light 33 entering the plasma generation region 25 is 40° to a position at which the angle is 80°.

According to this, a high EUV light concentration efficiency can be obtained by widely using an angle range in which the ion energy is low.

(14) According to the third embodiment, the EUV light concentrating mirror 23 is arranged such that the reflection surface 23a extends from a position at which the angle with respect to the direction opposite to the travel direction of the pulse laser light 33 entering the plasma generation region 25 is 35° to a position at which the angle is 100°.

According to this, a high EUV light concentration efficiency can be obtained by further widely using an angle range in which the ion energy is low. In other respects, the third embodiment is similar to the first embodiment.

### 6. EUV Light Concentrating Mirror 23 Having Through Hole 24 Surrounding Angle Range of 21°

### 6.1 Arrangement of EUV Light Concentrating Mirror 23

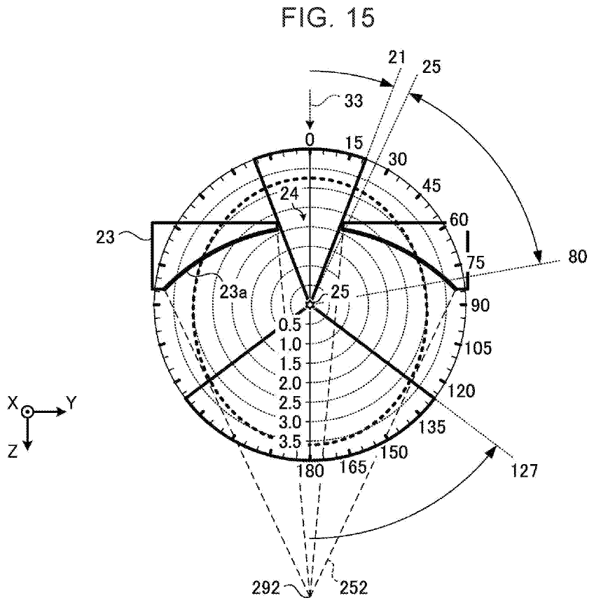

FIG. 15 shows the arrangement of the EUV light concentrating mirror 23 in a fourth embodiment. The outer edge of the reflection surface 23a viewed from the intermediate focal point 292 is substantially circular. The spatial distribution of the ion energy is similar to that shown in FIG. 9 and FIG. 10.

The EUV light concentrating mirror 23 according to the fourth embodiment is similar to that of the comparative example in that the through hole 24 thereof is positioned in the direction of 0°. The through hole 24 is larger than that in the comparative example, and the outer edge of the through hole 24 is arranged at a position where the angle with respect to the direction opposite to the travel direction of the pulse laser light 33 entering the plasma generation region 25 is larger than 21°. Thus, the EUV light concentrating mirror 23 is arranged such that the entire reflection surface 23a falls within an angle range in which the angle with respect to the direction opposite to the travel direction of the pulse laser light 33 entering the plasma generation region 25 is more than 21° and less than 127°.

However, when the angle range in which the reflection surface 23a is located is too narrow, the amount of the EUV light reaching the intermediate focal point 292 may be insufficient. It is preferable that the EUV light concentrating mirror 23 is arranged such that the reflection surface 23a extends from a position where the angle is 25° to a position where the angle is 80°. The EUV light concentrating mirror 23 may extend outside the angle range of being equal to or more than 25° and equal to or less than 80° as long as it falls within the angle range of being more than 21° and less than 127°.

### 6.2 Effect

(15) According to the fourth embodiment, the EUV light concentrating mirror 23 has the through hole 24 through which the pulse laser light 33 passes, and the outer edge of the through hole 24 is arranged at a position where the angle with respect to the direction opposite to the travel direction of the pulse laser light 33 entering the plasma generation region 25 is more than 21°.

According to this, by increasing the size of the through hole 24 through which the pulse laser light 33 passes, contamination of the reflection surface 23a in the vicinity of the through hole 24 can be suppressed.

(16) According to the fourth embodiment, the EUV light concentrating mirror 23 is arranged such that the reflection surface 23a extends from a position at which the angle with respect to the direction opposite to the travel direction of the pulse laser light 33 entering the plasma generation region 25 is 25° to a position at which the angle is 80°.

According to this, a high EUV light concentration efficiency can be obtained by widely using an angle range in which the ion energy is low.

In other respects, the fourth embodiment is similar to the third embodiment.

### 7. Others

### 7.1 Measurement of Ion Energy

### 7.1.1 Arrangement of Ion Detector

FIG. 16 shows a first example of an ion detector arranged to detect the ion energy. In order to detect the ion energy, an ion detector FC such as a Faraday cup is supported by a stage ST so as to be movable at a predetermined distance from the plasma generation region 25 in the chamber 2. The predetermined distance is, for example, 125 mm. The stage ST moves the ion detector FC along a movement path being in a plane parallel to the YZ plane including the plasma generation region 25 and having a constant distance from the plasma generation region 25. When the ion energy is measured, the EUV light concentrating mirror 23 may not be arranged in the chamber 2. Since the spatial distribution of the ion energy in this case is substantially axially symmetric with respect to the optical path axis of the pulse laser light 33, the ion energy in each direction can be measured by detecting the ion energy while moving the ion detector FC in the plane parallel to the YZ plane.

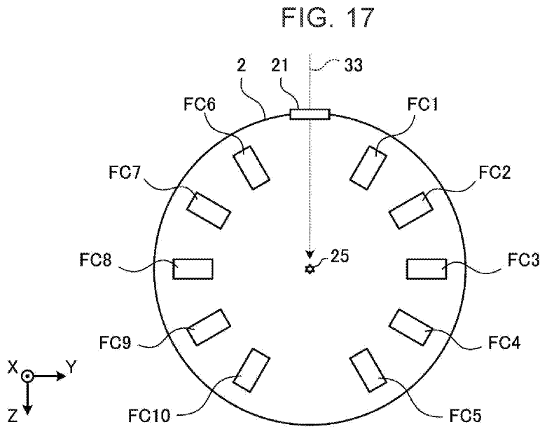

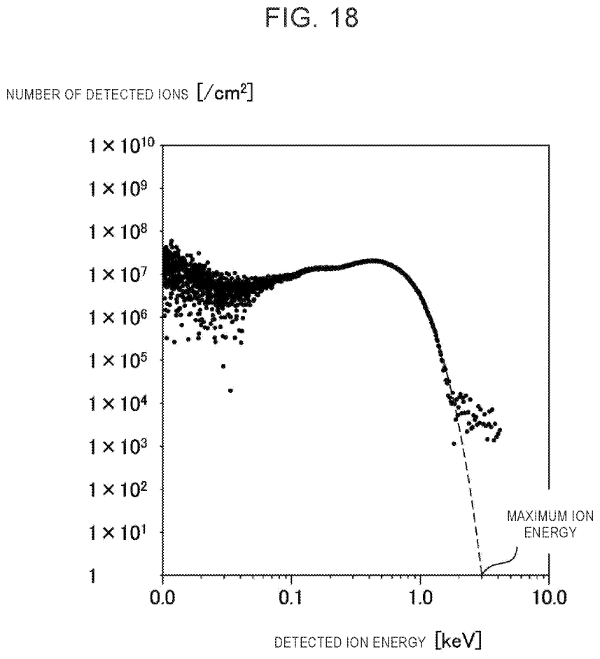

FIG. 17 shows a second example of an ion detector arranged to detect the ion energy. In the second example, a plurality of ion detectors FC1 to FC10 are arranged in the chamber 2. The ion detectors FC1 to FC10 are arranged at a plurality of positions corresponding to the movement path of the ion detector FC due to the stage ST shown in FIG. 16. By detecting the ion energy by each of the ion detectors FC1 to FC10, the ion energy in each direction can be measured.

### 7.1.2 Calculation Method of Ion Energy

FIG. 18 shows an example of a detection result by the ion detector. The detected ion energy and the number of detected ions per 1 cm² at one position inside the chamber 2 are plotted on a double logarithmic graph as shown in FIG. 18, and an approximation curve line is obtained by curve fitting. From the approximation curve line, the ion energy corresponding to the case in which the number of ions per unit area is one can be calculated as the maximum ion energy. The maximum ion energy is defined as the ion energy in each embodiment.

### 7.1.3 Effect

In each embodiment, the ion energy is the maximum ion energy at positions of the predetermined distance from the plasma generation region 25.

Since the maximum ion energy greatly affects the susceptibility to contamination, the contamination of the reflection surface 23a can be suppressed by arranging the reflection surface 23a in the region where the maximum ion energy is low.

(18) The maximum ion energy is the energy calculated by curve fitting as the ion energy corresponding to the case where the number of ions per unit area is one from the relationship between the detected ion energy and the number of detected ions detected at positions of the predetermined distance from the plasma generation region 25.

According to this, the estimated value of the maximum ion energy can be accurately calculated.

### 7. 2 Example of EUV Light Utilization Apparatus 6

FIG. 19 schematically shows the configuration of an exposure apparatus 6a connected to the EUV light generation system 11.

In FIG. 19, the exposure apparatus 6a as the EUV light utilization apparatus 6 (see FIG. 1) includes a mask irradiation unit 608 and a workpiece irradiation unit 609. The mask irradiation unit 608 illuminates, via a reflection optical system, a mask pattern of a mask table MT with the EUV light incident from the EUV light generation system 11. The workpiece irradiation unit 609 images the EUV light reflected by the mask table MT onto a workpiece (not shown) arranged on a workpiece table WT via a reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 20 schematically shows the configuration of an inspection apparatus 6b connected to the EUV light generation system 11.

In FIG. 20, the inspection apparatus 6b as the EUV light utilization apparatus 6 (see FIG. 1) includes an illumination optical system 603 and a detection optical system 606. The illumination optical system 603 reflects the EUV light incident from the EUV light generation system 11 to illuminate a mask 605 placed on a mask stage 604. Here, the mask 605 conceptually includes a mask blanks before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. A defect of the mask 605 is inspected based on the image of the mask 605 obtained by the above-described process, and a mask suitable for manufacturing an electronic device is selected using the inspection result. Then, the electronic device can be manufactured by exposing and transferring the pattern formed on the selected mask onto the photosensitive substrate using the exposure apparatus 6a.

### 7.3 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. An extreme ultraviolet light generation apparatus, comprising:
a chamber including a plasma generation region;
a target supply unit configured to supply a target to the plasma generation region;
a laser light concentrating mirror configured to concentrate pulse laser light on the plasma generation region; and
an EUV light concentrating mirror having a reflection surface reflecting extreme ultraviolet light radiated from the plasma generation region, and arranged such that the reflection surface falls within an angle range in which ion energy is less than an average value of the ion energy in a spatial distribution of the ion energy of ions diffused from the plasma generation region at positions of a predetermined distance from the plasma generation region.

2. The extreme ultraviolet light generation apparatus according to claim 1, further comprising:
a prepulse laser device configured to output prepulse laser light to be radiated to the target; and
a main pulse laser device configured to output the pulse laser light to be radiated to the target irradiated with the prepulse laser light,
wherein the laser light concentrating mirror concentrates both the prepulse laser light and the pulse laser light on the plasma generation region.

3. The extreme ultraviolet light generation apparatus according to claim 2,
wherein fluence of the prepulse laser light is equal to or more than 0.1 J/cm² and equal to or less than 100 J/cm²,
a pulse width of the prepulse laser light is equal to or more than 1 ps and equal to or less than 100 ns,
fluence of the pulse laser light is equal to or more than 10 J/cm² and equal to or less than 3000 J/cm², and
a pulse width of the pulse laser light is equal to or more than 1 ns and equal to or less than 100 ns.

4. The extreme ultraviolet light generation apparatus according to claim 2,
wherein fluence of the prepulse laser light is equal to or more than 1 J/cm² and equal to or less than 20 J/cm²,
a pulse width of the prepulse laser light is equal to or more than 1 ps and equal to or less than 100 ns,
fluence of the pulse laser light is equal to or more than 100 J/cm² and equal to or less than 2000 J/cm², and
a pulse width of the pulse laser light is equal to or more than 4 ns and equal to or less than 20 ns.

5. The extreme ultraviolet light generation apparatus according to claim 1,
wherein the average value is an average of the ion energy measured at each of a plurality of angles between 0° and 180° with respect to a direction opposite to a travel direction of the pulse laser light entering the plasma generation region.

6. The extreme ultraviolet light generation apparatus according to claim 1,
wherein the laser light concentrating mirror is arranged such that the pulse laser light passes outside the EUV light concentrating mirror and is concentrated on the plasma generation region.

7. The extreme ultraviolet light generation apparatus according to claim 1,
wherein the target contains tin,
a pulse width of the pulse laser light is in a range of being equal to or more than 3.6 ns and equal to or less than 4.4 ns, and
the angle range is a range of an angle being more than 90° and equal to or less than 180° with respect to a direction opposite to a travel direction of the pulse laser light entering the plasma generation region.

8. The extreme ultraviolet light generation apparatus according to claim 7,
wherein the EUV light concentrating mirror is arranged such that the reflection surface extends from a position at which an angle with respect to the direction opposite to the travel direction of the pulse laser light entering the plasma generation region is 95° to a position at which the angle is 150°.

9. The extreme ultraviolet light generation apparatus according to claim 1,
wherein the EUV light concentrating mirror is arranged such that the reflection surface falls within an angle range in which the ion energy is less than 90% of the average value.

10. The extreme ultraviolet light generation apparatus according to claim 1,
wherein the target contains tin,
a pulse width of the pulse laser light is in a range of being equal to or more than 3.6 ns and equal to or less than 4.4 ns, and
the angle range is a range of an angle being more than 125° and equal to or less than 180° with respect to a direction opposite to a travel direction of the pulse laser light entering the plasma generation region.

11. The extreme ultraviolet light generation apparatus according to claim 10,
wherein the EUV light concentrating mirror is arranged such that the reflection surface extends from a position at which an angle with respect to the direction opposite to the travel direction of the pulse laser light entering the plasma generation region is 130° to a position at which the angle is 165°.

12. The extreme ultraviolet light generation apparatus according to claim 1,
wherein the target contains tin,
a pulse width of the pulse laser light is in a range of being equal to or more than 18 ns and equal to or less than 22 ns, and
the angle range is a range of an angle being more than 21° and less than 127° with respect to a direction opposite to a travel direction of the pulse laser light entering the plasma generation region.

13. The extreme ultraviolet light generation apparatus according to claim 12,
wherein the EUV light concentrating mirror is arranged such that the reflection surface extends from a position at which an angle with respect to the direction opposite to the travel direction of the pulse laser light entering the plasma generation region is 40° to a position at which the angle is 80°.

14. The extreme ultraviolet light generation apparatus according to claim 12,
wherein the EUV light concentrating mirror is arranged such that the reflection surface extends from a position at which an angle with respect to the direction opposite to the travel direction of the pulse laser light entering the plasma generation region is 35° to a position at which the angle is 100°.

15. The extreme ultraviolet light generation apparatus according to claim 12,
wherein the EUV light concentrating mirror has a through hole through which the pulse laser light passes, and
an outer edge of the through hole is arranged at a position where an angle with respect to the direction opposite to the travel direction of the pulse laser light entering the plasma generation region is more than 21°.

16. The extreme ultraviolet light generation apparatus according to claim 12,
wherein the EUV light concentrating mirror has a through hole through which the pulse laser light passes, and is arranged such that the reflection surface extends from a position at which an angle with respect to the direction opposite to the travel direction of the pulse laser light entering the plasma generation region is 25° to a position at which the angle is 80°.

17. The extreme ultraviolet light generation apparatus according to claim 1,
wherein the ion energy is maximum ion energy at the positions of the predetermined distance.

18. The extreme ultraviolet light generation apparatus according to claim 17,
wherein the maximum ion energy is energy calculated, from relationship between detected ion energy and the number of detected ions detected at positions of the predetermined distance, by curve fitting as the ion energy corresponding to a case where a number of ions per unit area is one.

19. An electronic device manufacturing method, comprising:
generating extreme ultraviolet light using an extreme ultraviolet light generation apparatus;
outputting the extreme ultraviolet light to an exposure apparatus; and
exposing a photosensitive substrate to the extreme ultraviolet light in the exposure apparatus to manufacture an electronic device,
the extreme ultraviolet light generation apparatus including:
a chamber including a plasma generation region;
a target supply unit configured to supply a target to the plasma generation region;
a laser light concentrating mirror configured to concentrate pulse laser light on the plasma generation region; and
an EUV light concentrating mirror having a reflection surface reflecting the extreme ultraviolet light radiated from the plasma generation region, and arranged such that the reflection surface falls within an angle range in which ion energy is less than an average value of the ion energy in a spatial distribution of the ion energy of ions diffused from the plasma generation region at positions of a predetermined distance from the plasma generation region.

20. An electronic device manufacturing method, comprising:
inspecting a defect of a mask by irradiating the mask with extreme ultraviolet light generated by an extreme ultraviolet light generation apparatus;
selecting a mask using a result of the inspection; and
exposing and transferring a pattern formed on the selected mask onto a photosensitive substrate,
the extreme ultraviolet light generation apparatus including:
a chamber including a plasma generation region;
a target supply unit configured to supply a target to the plasma generation region;
a laser light concentrating mirror configured to concentrate pulse laser light on the plasma generation region; and
an EUV light concentrating mirror having a reflection surface reflecting the extreme ultraviolet light radiated from the plasma generation region, and arranged such that the reflection surface falls within an angle range in which ion energy is less than an average value of the ion energy in a spatial distribution of the ion energy of ions diffused from the plasma generation region at positions of a predetermined distance from the plasma generation region.
